(19) United States
(12) Patent Application Publication
(10) Pub. No.: US 2012/0223062 A1
(43) Pub. Date: Sep. 6, 2012

(54) Minimization of Surface Reflectivity

(75) Inventor: Andrew M. Hawryluk, Los Altos Hills, CA (US)

(73) Assignee: Ultratech, Inc., San Jose, CA (US)

(21) Appl. No.: 13/472,383

(22) Filed: May 15, 2012

Related U.S. Application Data
(62) Division of application No. 11/982,788, filed on Nov. 5, 2007, now abandoned.

(51) Int. Cl. H01L 21/268; B23K 26/00

(52) U.S. Cl. 219/121.85; 250/492.2; 250/492.22

(57) ABSTRACT

Apparatuses and methods are provided for processing a surface of a substrate. The substrate may have a surface pattern that exhibits directionally and/or orientationally different reflectivities relative to radiation of a selected wavelength and polarization. The apparatus may include a radiation source that emits a photonic beam of the selected wavelength and polarization directed toward the surface at orientation angle and incidence angle selected to substantially minimize substrate surface reflectivity variations and/or minimize the maximum substrate surface reflectivity during scanning. Also provided are methods and apparatuses for selecting an optimal orientation and/or incidence angle for processing a surface of a substrate.

### BACKGROUND OF THE INVENTION

1. Field of Invention

The invention relates generally to methods and apparatuses for processing a surface of a substrate using a photonic beam. More specifically, the invention relates to methods and apparatuses that carry out such processing in a manner that accounts for and/or minimizes reflectivity variations and/or the maximum surface reflectivity of a surface of a substrate relative to the photonic beam.

2. Description of Related Art

Fabrication of semiconductor-based microelectronic devices such as processors, memories and other integrated circuits (ICs) require thermal processes. For example, the source/drain portions of transistors may be formed by exposing regions of a silicon wafer substrate to accelerated dopants containing boron, phosphorous or arsenic atoms. After implantation, the interstitial dopants are electrically inactive and require activation. Activation may be achieved by heating the entirety or a portion of the substrate to a particular processing temperature for a period of time sufficient for the crystal lattice to incorporate the impurity atoms into its structure.

In general, it is desirable to activate or anneal semiconductor substrates in a manner that produces well-defined shallow doped regions with very high conductivity. This may be done by rapidly heating the wafer to temperatures near the semiconductor melting point to incorporate dopants at substitutional lattice sites, and then rapidly cooling the wafer to “freeze” the dopants in place. The rapid heating and cooling result in an abrupt change in dopant atom concentration, with a depth defined by the implant process.

Activation may be carried out via flash lamp or laser technology. Laser-based technologies are often preferred over conventional heat lamp technologies for annealing because the time scales associated with laser-based technologies are much shorter than those associated with conventional lamps. As a result, thermal diffusion for laser-based annealing processes plays a lesser role in the diffusion of the impurity atoms through the lattice structure than for convention Rapid Thermal Annealing (RTP) technologies employing conventional lamps (unpolarized flash lamps) to heat the wafer surface.

Exemplary terminology used to describe laser-based thermal processing techniques include laser thermal processing (LTP), laser thermal annealing (LTA), and laser spike annealing (LSA). In some instances, these terms can be used interchangeably. In any case, these techniques typically involve forming a laser beam into a long, thin image, which in turn is scanned across a surface to be heated, e.g., an upper surface of a semiconductor wafer. For example, a 0.1-mm wide beam may be raster scanned over a semiconductor wafer surface at 100 mm/s to produce a 1-millisecond dwell time for the heating cycle. A typical maximum temperature during this heating cycle might be about 1350° C. for silicon wafers. Within the dwell time needed to bring the wafer surface up to the maximum temperature, a layer only about 100 to about 200 micrometers below the surface region is heated. Consequently, the bulk of the millimeter thick wafer serves to cool the surface almost as quickly as it was heated once the laser beam is past. Additional information regarding laser-based processing apparatuses and methods can be found in U.S. Pat. No. 6,747,245 and U.S. Patent Application Publication Nos. 20040188396, 20040173585, 20050067384, and 20050103998 each to Talwar et al.

LTP may employ either pulsed or continuous radiation from any of a number of sources. For example, conventional LTP may use a continuous, high-power, CO₂ laser beam, which is raster scanned over the wafer surface such that all regions of the surface are exposed to at least one pass of the heating beam. Similarly, a continuous radiation source in the form of laser diodes may be used in combination with a continuous scanning system.

In general, illumination uniformity (both macro- and micro-uniformity) over the useable portion of the laser beam image is a highly desirable trait. This ensures that the corresponding heating of the substrate is correspondingly uniform. Similarly, the energy delivered from the laser should be generally stable over time, e.g., energy per pulse for pulse radiation applications and laser beam power for continuous radiation applications, so all exposed regions are successively heated to a uniform temperature. In short, illumination uniformity and stability is generally a desirable characteristic for any laser used for semiconductor annealing applications.

In many laser thermal processing techniques, a photonic beam of appropriate polarization (p-polarized light) is shaped to form an image on a portion of a silicon wafer surface. In such techniques, the image may be generally elongate in shape and scanned over substantially the entire wafer surface. Since uniform wafer surfaces (e.g., bare or unpatterned) exhibit uniform light absorption behavior, a uniform surface will uniformly absorb most of the energy from a beam of proper polarization and at or near the Brewster's angle for the surface (e.g., ˜75° incidence). Consequently, it is a fairly straightforward matter to tailor a beam to heat a uniform substrate surface to a uniform peak temperature simply by selecting an appropriate scan path and rate.

Wafers with nonuniform surfaces (e.g., processed or patterned wafers), however, represent a particularly difficult challenge. Items such as devices and conductive pathways on wafer surfaces can hinder uniform light absorption. For example, devices on silicon wafers are often formed from materials other than silicon. Different materials may exhibit different Brewster's angles. Even when substantially the same material are deposited on wafer surfaces, interfaces formed between the deposited and native materials may scatter light or alter reflectivities to light. Thus, regardless whether flash lamp or laser technologies are used, reflectivity differences may cause the energy source to heat different portions of a nonuniform wafer surface differently.

It has been discovered that certain patterned wafer surfaces exhibit different reflectivities depending on the incidence angle of the beam striking the surface, orientation of the wafer surface relative to the beam, and/or polarization of beam relative to the surface. One important implication of this discovery is that uniform heating may be achieved by controlling the directionality and the polarization of the beam relative to the wafer surface. Another implication is that apparatuses may be set up to account for and exploit such reflectivity differences to improve the uniformity of laser thermal processing of wafer surfaces.

Thus, it is evident that opportunities exist in the art to improve thermal processes and to overcome the drawbacks associated with known technologies for semiconductor annealing applications.

### SUMMARY OF THE INVENTION

In a first aspect, the invention provides an apparatus for processing a surface of a substrate having a surface normal and a surface pattern. The apparatus may, for example, include a radiation source, a stage, a relay, an alignment system, and a controller. The radiation source emits a photonic beam. The stage supports and moves the substrate relative to the beam. The relay directs the photonic beam from the radiation source toward the substrate at an incidence angle relative to the surface normal. The alignment system positions the substrate on the stage so the pattern is disposed at an orientation angle relative to the beam. The controller is operably coupled to the radiation source, relay, alignment system and/or stage and provides relative scanning movement between the stage and the beam. The controller maintains the orientation angle and incidence angle at values selected to substantially minimize substrate surface reflectivity variations and/or minimize the maximum substrate surface reflectivity during scanning.

For example, a CO₂ laser may be used to emit a p-polarized beam with respect to the substrate surface. The orientation angle may be fixed relative to the substrate surface. Optionally, the incidence angle may be adjustable. When the substrate surface exhibits a Brewster's angle, the incidence angle value may be within about ±10° of the Brewster's angle. As substrate materials vary, so will the Brewster's angle for the substrate. For example, the Brewster's angle for a silicon substrate is about 75°. For such substrate, the incidence angle value may be within a range of about 65° to about 85° relative to the surface normal.

In another aspect, the invention provides a method for processing a surface of a substrate as described above. The method involves: producing a photonic beam; directing the beam toward the substrate surface at an incidence angle with respect to the surface normal and at an orientation angle relative to the surface pattern; and scanning the beam across the substrate. Typically, the beam is p-polarized, and the orientation angle is fixed relative to the polarization of the beam. In addition, the incidence angle may be non-normal to the surface but adjustable with respect the surface normal. In any case, the beam may be scanned across the substrate while maintaining the orientation angle and incidence angle at values selected to substantially minimize substrate surface reflectivity variations and/or minimize the maximum substrate surface reflectivity during scanning.

The beam is scanned in a manner so that after scanning, substantially the entire substrate surface has been heated to a uniform peak temperature. Depending on the substrate, the peak temperature requirement may differ. For example, while the peak temperature may be greater than about 1300° C. for annealing silicon-based material, the peak temperature may be as low as 1200° C. for substrates that contain a relatively high percentage of germanium. In any case, the beam may be scanned in a manner so that after scanning, substantially the entire substrate surface has been heated to the uniform peak temperature for a period of time that does not exceed about 1 ms.

In a further aspect, the invention provides an apparatus for processing a surface of a substrate, e.g., a substrate having a surface pattern that exhibits directionally and/or orientationally different reflectivities relative to radiation of a selected wavelength and polarization. The apparatus includes a radiation source, a relay, a stage, and a controller. The radiation source emits a photonic beam of the selected wavelength and polarization. The relay directs the photonic beam from the radiation source toward the substrate an incidence angle relative to the substrate surface normal. The stage supports the substrate at an orientation angle relative to the beam. The controller is operably coupled to the radiation source, relay, and/or stage. In operation, the controller provides relative scanning movement between the stage and the beam while maintaining the orientation angle and incidence angle at values selected to minimize substantially substrate surface reflectivity variations and/or maximum substrate surface reflectivity during scanning.

The radiation source may be keyed to the substrate. For example, the radiation source may emit a photonic beam of a wavelength and polarization selected to generally minimize the reflectivity and/or the reflectivity variation for the substrate and pattern type. In some instances, the substrate may comprise or consist essentially of a semiconductor material such as silicon, germanium, and alloys thereof. In particular, the substrate surface toward which the beam is directed may include a semiconductor such as silicon, e.g., silicon on insulator. In addition, the surface pattern may include electrically conductive materials such as metals, e.g., copper, gold, silver, aluminum, etc.

The surface pattern may be formed from a plurality of electrically conductive structures that tend to be oriented in a specific direction on the substrate. For example, the structures may each have a length and width, the lengths define lengthwise axes, and the structures are aligned so their lengthwise axes are parallel to each other. In such a case, the structures have a dominant orientation direction along the lengthwise axes. In addition, the widths of the structures may be orthogonal to the dominant orientation direction. In such a case, the widths may be much less than the beam wavelength. For example, widths may exceed no more than about 1% to about 5% of the wavelength.

In still another aspect, a method is provided for processing a surface of a substrate as described above, by using a photonic beam of a wavelength and polarization selected to generally minimize the reflectivity and/or the reflectivity variation for the substrate type. The method may be carried out so that the substrate surface reflectivity variations do not exceed about 10% to about 20%.

In a yet further aspect, methods and apparatuses are provided for selecting an optimal orientation and/or incidence angle for processing a surface of a substrate as generally described above with a photonic beam of a selected wavelength and polarization. The beam is directed toward the substrate surface at an incidence angle and scanned with respect to the substrate surface. By measuring radiation reflected from the substrate while rotating the substrate about its surface normal and/or changing the incidence angle, the optimal orientation and/or incidence angles may be determined that correspond to a minimum in substrate surface reflectivity variations and/or minimum in the overall or the peak substrate surface reflectivity.

Additional embodiments of the invention will be apparent from the disclosure contained herein.

### BRIEF DESCRIPTION OF THE DRAWINGS

FIG. 1 schematically depicts a simplified exemplary embodiment of the inventive thermal processing apparatus.

FIG. 2 shows a graph that plots the reflectivities of a bare silicon wafer surface relative to a patterned wafer surface over a range of incidence angles to a beam of p-polarized radiation.

FIG. 3 depicts an exemplary patterned silicon wafer having a nonmetallic transistor structure (gate) of low reflectivity.

FIG. 4 depicts an exemplary patterned silicon wafer having a metal gate structure of a high reflectivity.

FIG. 5 depicts how electrical current may flow within the metal layer of the structure shown in FIG. 4 in response to a beam's electric field.

FIG. 6 graphically shows how a longer wire may exhibit a higher reflectivity relative to a shorter wire due to differences in current induction for radiation of a particular wavelength.

FIGS. 7A and 7B, collectively FIG. 7, show a wafer having a plurality of differently shaped structures on its surface that is illuminated by a beam of incident radiation. FIG. 7A shows the wafer in top view. FIG. 7B shows the wafer in cross-sectional view along dotted line A.

FIG. 8 shows an exemplary patterned silicon wafer similar to that shown in FIG. 4 with the structure oriented perpendicularly relative to a beam's electric field.

FIG. 9 graphically depicts a plot of estimated reflectivities of the same silicon surface with metal structure in two different orientations relative to the reflectivity of a bare silicon surface over a range of angles of incidence.

FIG. 10 depicts an experimental setup that shows how an plurality of elongate surface structures may render the reflectivity of a surface directionally and/or orientationally different relative to a beam of p-polarized radiation.

FIG. 11 shows a plot of the differences in reflectivity versus probability density for a wafer based on experimental results.

The drawings are intended to illustrate various aspects of the invention, which can be understood and appropriately carried out by those of ordinary skill in the art. The drawings may not be to scale as certain features of the drawings may be exaggerated for emphasis and/or clarity of presentation.

### DETAILED DESCRIPTION OF THE INVENTION

### Definitions and Overview

Before describing the present invention in detail, it is to be understood that this invention, unless otherwise noted, is not limited to specific substrates, lasers, or materials, all of which may vary. It is also to be understood that the terminology used herein is for the purpose of describing particular embodiments only, and is not intended to be limiting.

It must be noted that, as used in this specification and the appended claims, the singular forms “a”, “an” and “the” include both singular and plural referents unless the context clearly dictates otherwise. Thus, for example, reference to “a beam” includes a plurality of beams as well as a single beam, reference to “a wavelength” includes a range or plurality of wavelengths as well as a single wavelength, and the like.

In describing and claiming the present invention, the following terminology will be used in accordance with the following definitions.

The terms “Brewster's angle” or “Brewster angle” is used to refer to the angle of incidence between a radiation beam and a surface that corresponds to the minimum or near-minimum reflectivity of the P-polarized component of the beam. Films on the surface of an object, such as a silicon wafer, may prevent it from exhibiting zero reflectivity at any angle. There generally will be an angle of minimum reflectivity for P-polarized radiation. Accordingly, the Brewster's angle as used herein for a specular surface formed from a variety of different films stacked on a substrate can be thought of as having an effective Brewster's angle, which is the incident angle at which the reflectivity of P-polarized radiation is at a minimum. This minimum angle typically coincides with or is near the angle of the Brewster's angle for the substrate material.

The term “intensity profile” in reference to an image or a beam refers to the distribution of the integrated radiation intensity along one or more dimensions. For example, an image may have a useful portion and a non-useful portion. The useful portion of an image typically has a “uniform” or constant integrated intensity profile over some portion of its length. In other words, the intensity profile integrated in the scan direction throughout the useful portion of the image may be substantially constant. Accordingly, any point on a substrate surface region that is scanned by a useful portion of an image having a uniform intensity profile will be heated to the same temperature. However, the intensity or intensity profile of the non-useful portion may differ from that of the useful portion. Thus, the image as a whole may have an overall “non-uniform” intensity profile even though a useful portion by itself may exhibit a uniform intensity profile.

As a related matter, the term “peak intensity value” of an image or a beam refers to the point along the beam length exhibiting the highest integrated intensity across the beam width. Typically, the entirety of the useful portion of an image will exhibit an integrated intensity very close to the peak integrated intensity.

As another related matter, the term “energy utilization” as in the “energy utilization of an image” refers to the proportion of energy associated with the portion of the image useful for producing a desired effect relative to the total beam energy in the image. For example, in an annealing application the “useful portion” of an image may be only that part of the beam that comes within about a percent or two of the maximum or peak beam intensity. In such a case, the “useful portion” exhibits a “substantially uniform” intensity. A small modification to the image profile shape can produce a large change in the “energy utilization.”

The term “semiconductor” is used to refer to any of various solid substances having electrical conductivity greater than insulators and less than good conductors, and that may be used as a base material for computer chips and other electronic devices. Semiconductors include elements such as silicon and germanium and compounds such as silicon carbide, aluminum phosphide, gallium arsenide, and indium antimonide. Unless otherwise noted, the term “semiconductor” includes any one or a combination of elemental and compound semiconductors, as well as strained semiconductors, e.g., semiconductors under tension or compression. Exemplary indirect bandgap semiconductors suitable for use with the invention include Si, Ge, and SiC. Direct bandgap semiconductors suitable for use with the invention include, for example, GaAs, GaN, and InP.

The terms “substantial” and “substantially” are used in their ordinary sense and refer to matters that are considerable in importance, value, degree, amount, extent or the like. For example, the phrase “substantially Gaussian in shape” refers to a shape that corresponds predominantly to the shape of a Gaussian curve. However, a shape that is “substantially Gaussian” may exhibit some characteristics of a non-Gaussian curve as well, e.g., the curve may also include a non-Gaussian component.

Similarly, a “substantially uniform” intensity profile will contain a relatively flat portion where the intensity does not deviate more than a few percent from the profile's peak intensity. Preferably, the intensity deviation is less than about 5%. Optimally, the intensity deviation is no more than about 1% or no more than about 0.8%. Other uses of the term “substantially” involve an analogous definition.

The term “substrate” as used herein refers to any material having a surface, which is intended for processing. The substrate may be constructed in any of a number of forms, for example, such as a semiconductor wafer containing an array of chips, etc.

As discussed above, the invention generally provides for apparatuses and methods for thermally processing a substrate surface using a photonic beam, minimizing the reflectivity from the structures on the surface of the substrate, and promoting of surface reflectivity uniformity. The apparatuses and methods typically involve thermal processing techniques carried out in a manner that accounts for and/or controls the orientational and/or directional relationship between the photonic beam and the substrate surface. The invention may be carried out in a manner that substantially minimize substrate surface reflectivity variations and/or minimize the maximum substrate surface reflectivity during scanning.

Also provided are apparatuses and methods for selecting an optimal substrate orientation and/or beam incidence angle for processing a surface of a substrate, e.g., one of a group of similar substrates, with a photonic beam of a selected wavelength and polarization. The substrate surface exhibits different reflectivities depending on the orientational or directional relationship between itself and the beam. Variations in reflectivities may be associated with patterns on the substrate surface.

### Exemplary Laser-Based Thermal Processing Technology

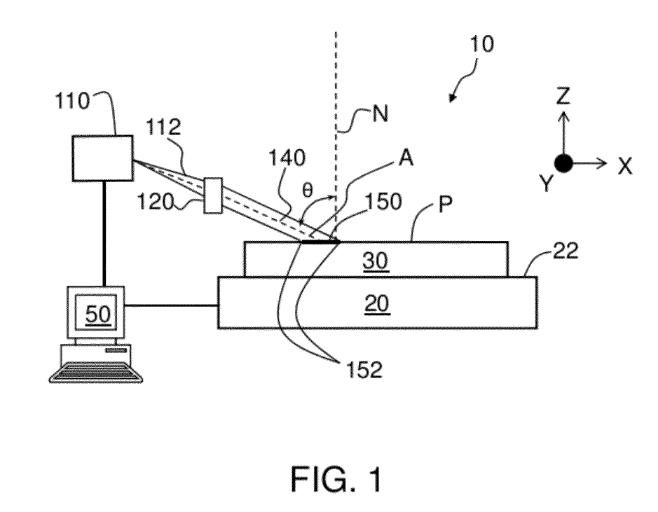

In general, the invention may be used to form apparatuses for carrying out rapid thermal semiconductor processing. For example, FIG. 1 is a schematic diagram of a simplified exemplary embodiment of a thermal processing apparatus 10 that may be used to anneal and/or otherwise thermally process one or more selected surface regions of a substrate according to the present invention. LTP system 10 includes a movable substrate stage 20 having an upper surface 22 that supports a semiconductor substrate 30 having an upper surface P and a surface normal, N, thereto. Substrate stage 20 is operably coupled to controller 50. Substrate stage 20 is adapted to move in the X-Y plane under the operation of controller 50 so the substrate can be scanned relative to the image generated from radiation provided by radiation source 110. The stage 20 may also controllably rotate substrate 30 about an axis Z which extends orthogonally relative to the X-Y plane. As a result, the stage 20 may controllably fix or alter the orientation of substrate 30 in the X-Y plane.

In some instances, the stage may include different components to carry out different functions. For example, an alignment system may be provided to position the substrate on the stage at a variable orientation angle relative to the surface normal. In such a case, the stage may independently control the substrate movement while the alignment system controls the substrate orientation.

The radiation source 110 is operably coupled to controller 50, and a relay 120 that serves to relay radiation generated by the radiation source toward the substrate to form an image on its surface. In an exemplary embodiment, radiation source 110 is a CO₂ laser that emits radiation at a wavelength λ_{H}˜10.6 μm (heating wavelength) in the form of beam 112. However, the radiation suitable for use with the invention may include LED or laser diode radiation as well, e.g., radiation having a wavelength of about 0.8 μm. Optionally, a plurality of radiation sources may be employed. As shown, the laser 110 generates an input beam 112 that is received by a relay 120 that is adapted to convert the input beam to an output beam that forms an image on the substrate.

Optionally, the intensity profile of the beam is manipulated so a portion of the image intensity is rendered uniform about its peak intensity for even heating and high energy utilization. For example, the relay 120 may transform the input beam 112 into output beam 140. The relay may be constructed in a manner to provide for desired coherent beam shaping so the output beam exhibits a uniform intensity profile over a substantial portion thereof. In short, the relay 120 and the radiation source 110 in combination may stabilize, the directionality, intensity profile, and phase profile of the output beam to produce a consistently reliable laser annealing system.

Beam 140 travels along optical axis A, which makes an angle θ with a substrate surface normal N. Typically, it is not desirable to image a laser beam on a substrate at normal incidence, because any reflected light may cause instabilities when it returns to the laser cavity. Another reason for providing optical axis A at an incidence angle θ other than at normal incidence, is that efficiently coupling of beam 140 into the substrate 30 may best be accomplished by judicious choice of incidence angle and polarization direction, e.g., making the incidence angle equal to the Brewster's angle for the substrate and using p-polarized radiation. In any case, the stage may be adapted to scan the substrate through the beam position while preserving or altering the incidence angle. Similarly, the stage may be adapted to control, fix or vary the orientation angle of the substrate relative to the beam. The selection of the incidence and/or orientation angle is discussed below.

Beam 140 forms image 150 at substrate surface P. In an exemplary embodiment, image 150 is an elongate image, such as a line image, having its lengthwise boundaries indicated at 152, and located within a plane containing the incident beam axis and the surface normal. Accordingly, the incidence angle of the beam (θ) relative to the substrate surface may be measured in this plane.

The controller may be programmed to provide relative movement between the stage and the beam. As a result, the image may be scanned across the substrate surface to heat at least a portion of the substrate surface. Such scanning may be carried out in a manner effective to achieve a desired temperature within a predetermined dwell time, D. Scanning may typically be performed in a direction that is orthogonal to the lengthwise axis of the image although this is not a firm requirement. Non-orthogonal and non-parallel scanning may be carried out as well. A means may also be included to provide feedback of the uniformity in maximum temperature achieved. Various temperature measuring means and methods may be used with the invention. For example, a detector array might be used to take a snap-shot of the emitted radiation distribution over the surface or multiple snap-shots might be used to derive a map of the maximum temperature as a function of the position across the length of the beam image. Optionally, a means for measuring the intensity profile of the beam on the substrate may be used as well.

Optimally, a real-time temperature measurement system may be employed that can sense the maximum temperature with a spatial resolution preferably comparable to the thermal diffusion distance and with a time constant less than or preferably comparable to the dwell time of the scanned beam. For example, a temperature measurement system may be used that samples the emitted radiation 20,000 times a second at 256 points spread evenly over a 20 mm line-image length. In some instances, 8, 16, 32, 64, 128, 256, 512, or more distinct temperature measurements may be made at a rate of 100, 1000, 10,000, 50,000 line scans per second. An exemplary temperature measurement system is described in U.S. Patent Application Publication No. 2006/0255017, entitled “Methods and Apparatus for Remote Temperature Measurement of a Specular Surface,” published on Nov. 16, 2006. Such temperature measurement systems may be used to provide input to the controller so appropriate corrections can be made possibly by adjusting the radiation source, the relay or the scanning velocity.

### Absorption (or Reflection) Differences

To elucidate the novel and nonobvious aspects of the invention, theoretical and practical aspects of the absorption/reflection behavior of substrate surfaces relative to photonic beams are discussed below. In particular, the discussion focuses on directionally and/or orientationally dependent absorption/reflection behavior of patterned semiconductor wafer surface relative to p-polarized laser beams and in particular, patterned metallic-like structures.

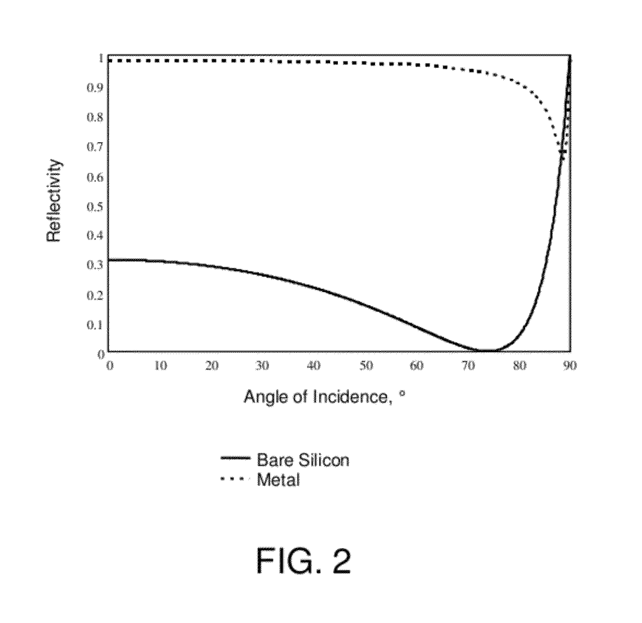

As discussed above, it has been discovered that certain patterned wafer surfaces exhibit different reflectivities depending on the incidence angle of the beam striking the surface, orientation of the wafer surface relative to the beam, and/or polarization of beam relative to the surface. It has also been discovered that the reflectivities of these patterned wafer surfaces differ from those of unpatterned wafer surfaces for a given range of incidence angles, orientation angles, and beam polarizations. For example, FIG. 2 shows a graph that plots the reflectivities to a beam of p-polarized radiation from a CO₂ laser over a range of incidence angles for: (1) a bare (unpatterned) silicon wafer surface (solid line); and a metal surface (dashed line). From visual inspection of the reflectivities, it can be seen that the Brewster's angle for bare silicon surface is about 75° but the Brewster's angle for the metal surface is closer to about 87°. It is also evident that the minimum reflectivity for the metal surface is higher than that for the bare wafer. It is further evident that the metal surface at most incidence angles is more reflective than the bare wafer surface.

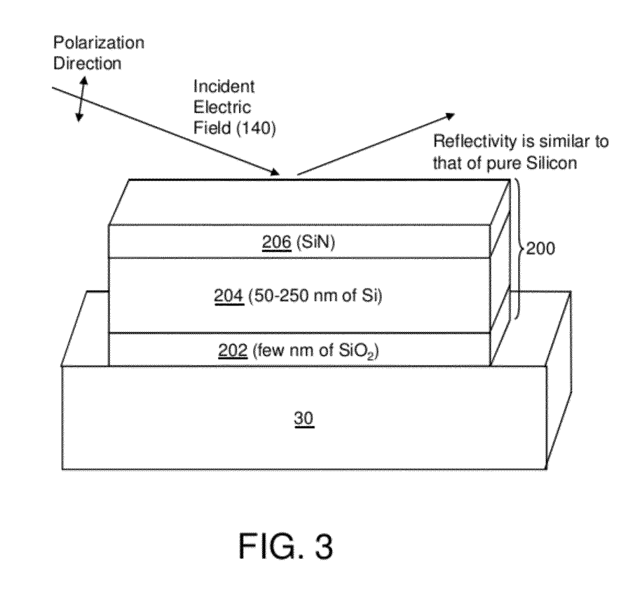

Such discrepancies in reflectivity can be explained in view of the structures associated with patterned wafer surfaces. A hypothetical gate-like structure for a semiconductor device is illustrated in FIG. 3, where the gate is comprised mostly of semiconductor and dielectric matter whose optical properties are similar to those of bulk silicon. Patterned silicon wafers 30 may contain a large number of these transistor structures such as gates 200 that contain a silicon dioxide layer 202, a silicon layer 204, and a silicon nitride layer 206. Such structures are somewhat typical of devices seen in the modern day semiconductor industry, however this invention is not limited to the applications within the semiconductor industry. During certain thermal processing techniques, a laser beam 140 may be directed to such a structure. Because the optical properties (absorption and reflection) of the structures in the gate-like regions are similar to those of bulk silicon, their absorption and reflection characteristics are similar, and it is possible to achieve relatively uniform temperatures on the structures.

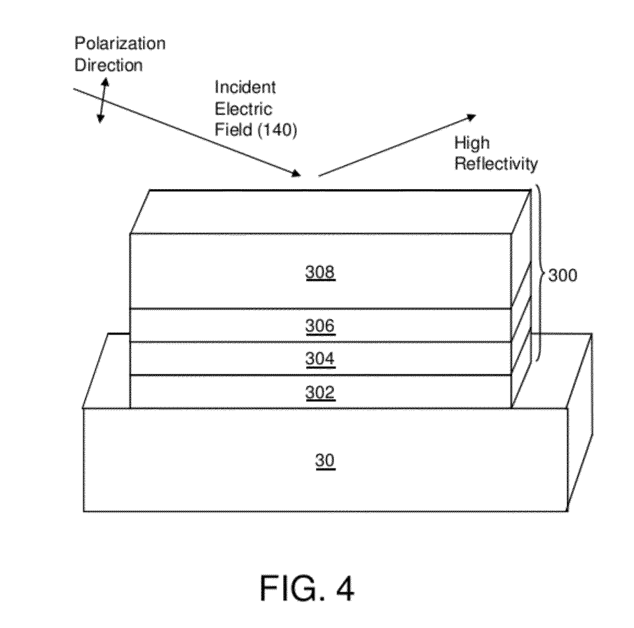

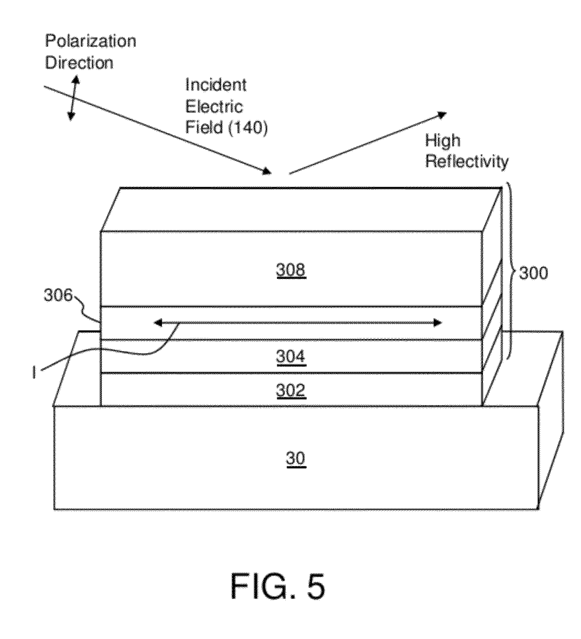

Deviations from uniform beam-energy absorption create deviations in temperature uniformity. These deviations in absorption often occur when the materials in surface structures differ significantly from those shown in FIG. 3. FIG. 4 depicts a hypothetical metal gate structure that might be found in memory structures or in advanced logic (“high-k, metal gate”) structures. The gate 300 includes a high-K material layer 302, a silicon layer 304, a metal layer 306, and a silicon nitride layer 308. Other layers and materials can be used. Additional layers can be added or subtracted. When p-polarized beam 140 strikes the gate 300, electrical surface currents are produced within the metal. Given an appropriate beam wavelength, as shown in FIG. 5, electrical current may flow within the metal layer in response to the electric field of the beam. Naturally, the electrical current flows in a direction consistent with the polarization of the beam (as indicated by double headed arrow I). The reflectivity of the layer to the beam generally varies proportionally with electrical current flow.

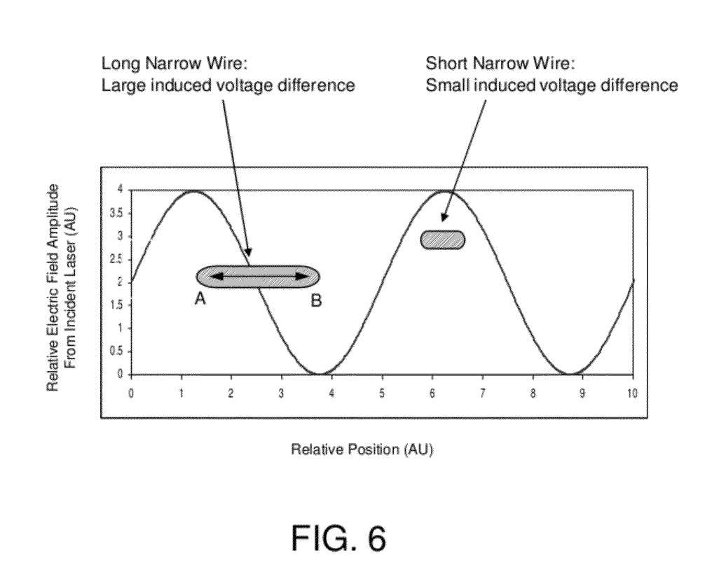

To illustrate, metals or other conductive materials in a wafer surface structure may be thought of as a wire dipole antenna having an “antenna length”. As shown in FIG. 6, a sine wave, representing the amplitude of a polarized electric field from a p-polarized incident beam, is plotted in general dimensional scale to long and short wires exposed to the beam. The longer wire has an antenna length of approximately one-half of the wavelength of the sine wave. This wire has a large positive induced voltage at position A, but has nearly zero voltage at position B. The large voltage difference creates an alternating current in the wire (illustrated as the double ended arrow) which ultimately reflects the electric field. In contrast, the induced voltage difference at the ends of the shorter wire is much smaller due to its shorter antenna length. Hence, the induced current and reflectivity of the shorter wire are both lower than that of the longer wire.

It should be noted that the mere existence of reflected electric energy means that at least some of the incident energy is not absorbed in this region. Therefore, one can conclude that the amount of energy absorbed in the regions with metal-like structures will be less than the areas with no (or fewer) metal-like structures. This difference in absorbed energy will lead directly to non-uniform temperatures on the wafer.

Because metal structures typically cover only a portion of the substrate surface, some wafer surface regions (e.g., high dielectric regions) may exhibit very little reflectivity while other regions (e.g., highly conductive metal regions) may exhibit a much higher reflectivity. Such regional variations in reflectivity to the beam results in large differences in localize beam energy absorption. As a result, large differences may result in the surface temperature of the substrate.

### Apparatus and Processing Design and Implementation

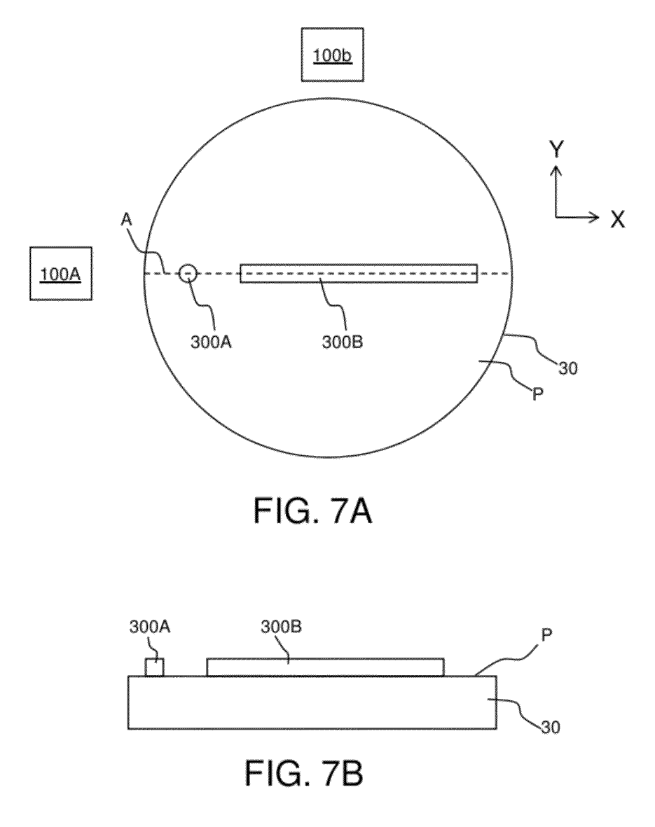

From the above discussion, it should be apparent that the shapes of structures on a wafer surface as well as their orientation angle relative to radiation polarization may have a strong influence on the reflectivity of the structures. As shown in FIG. 7, a wafer 30 may have a plurality of differently shaped structures, indicated at 300A and 300B, on it upper surface P. As shown in FIG. 7A, structure 300A has a circular shape with a diameter of D, and structure 300B has a rectangular shape with a width of D and a length of 100D. As shown in FIG. 7B, both structures 300A and 300B are similar to the structure 300 shown in FIG. 4.

Also as shown in FIG. 7A, two p-polarized radiation sources 100A and 110B are provided that illuminate the wafer surface from directions that run parallel to axes X and Y, respectively. When p-polarized radiation from source 100A strikes structures 300A and 300B, both structures exhibits the same effective antenna length D. In contrast, when p-polarized radiation from source 100B strikes structures 300A and 300B, the effective antenna length for structure 300B is about 100 times as long as the effective antenna length for structure 300A. Those of ordinary skill in the art will recognize that, for this example, the antenna length for structure 300A is generally independent of its orientation angle relative to the illuminating radiation, whereas the antenna length for structure 300B can vary over a range of D to 100D depending on the structure's orientation angle.

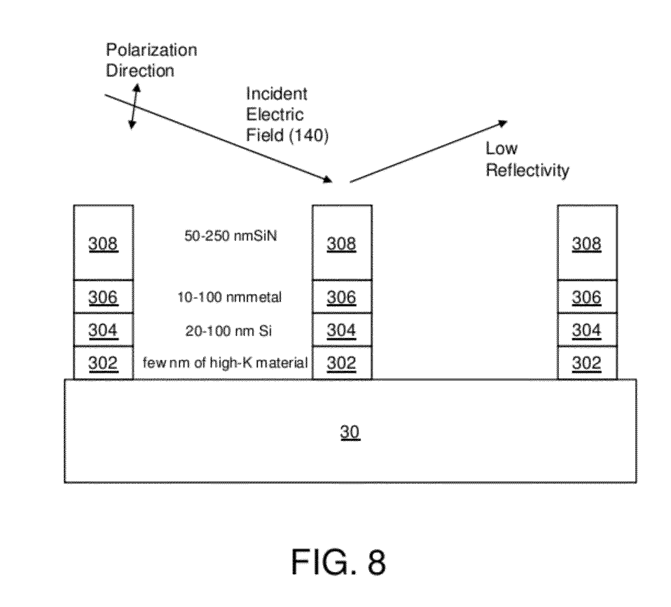

Thus, it is possible to reduce or substantially eliminate the reflectivity differences between the different regions on the wafer relative to a beam of p-polarized radiation. For example, it is possible to reduce the difference in reflectivity (and absorptivity) by appropriately choosing the orientation of a metal structure (relative to the incident electric field) and the angle of incidence. As shown in FIG. 8, this may be done, for example, by rotating a substrate having structures similar to those shown in FIG. 4 so the orientation of the metal structure has its long axis perpendicular to the polarization vector of the incident electric field. That is, the lengths of the structures are substantially perpendicular to the plane of polarization of the incident laser beam. Such an arrangement will effectively reduce the reflectivity of the structure to the incident radiation, as long as the antenna length is substantially shorter than the radiation wavelength.

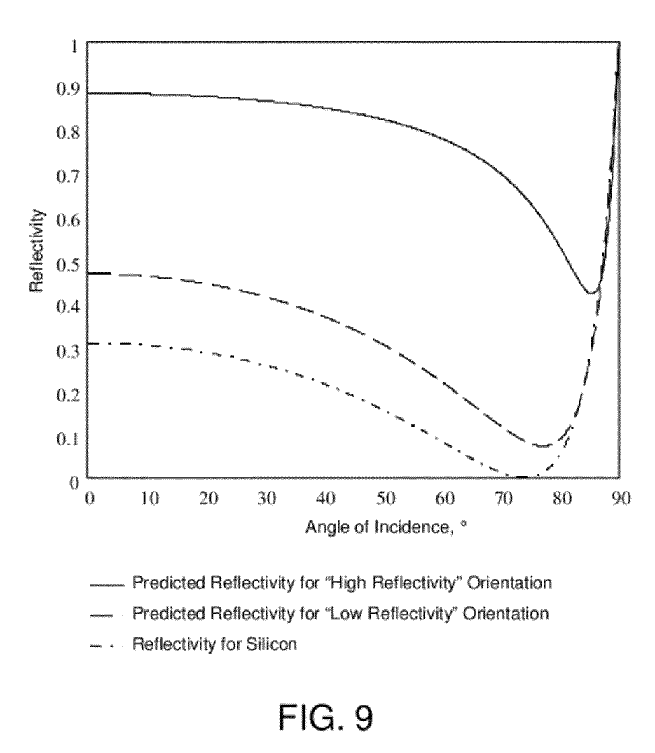

FIG. 9 graphically depicts a plot of estimated reflectivities of the same surface with metal structure in two different orientations as well as a plot of the reflectivity from bulk silicon over a range of angles of incidence. These plots assume p-polarized incident radiation. The reflectivity of the structure relative to radiation having an electric field vector in the plane of the long dimension of the metal structure is much higher than the reflectivity of the structure relative to radiation having an electric field vector is perpendicular to the long dimension.

Notably, at an incidence angle of 75°, the reflectivity difference between the silicon and metal structure can be greater than 50% for one orientation, whereas in the reflectivity difference can be less than 10% in the proper orientation. Also notably, it is possible to match the reflectivity of the two regions exactly when the incidence angle is greater than about 75°, e.g., approximately 82° or larger.

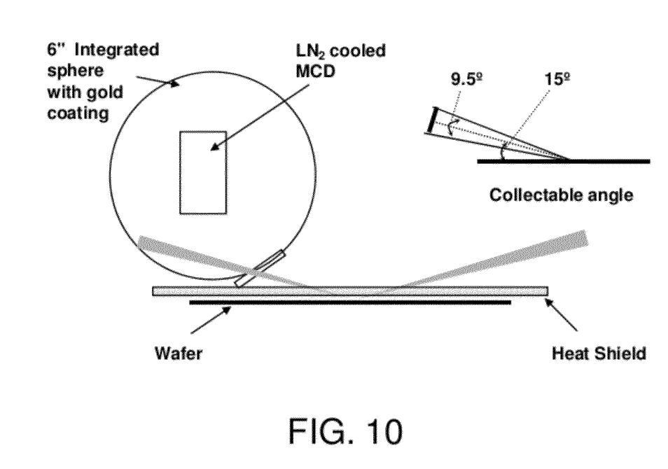

FIG. 10 shows the setup for an experiment that demonstrated how a plurality of elongate surface structures renders the reflectivity of a surface directionally and/or orientationally different relative to a beam of p-polarized radiation. The experimental setup employed a metal structure similar to that of a metal-gate DRAM structure. The metal structures were formed from a ˜50 nm-thick metal layer on a silicon wafer surface. A ˜100 nm-thick layer of polysilicon was deposited above the metal layer. The metal structures were each approximately 100 nm in width by 1000 nm in length, with a repeat distance of approximately 300 nm.

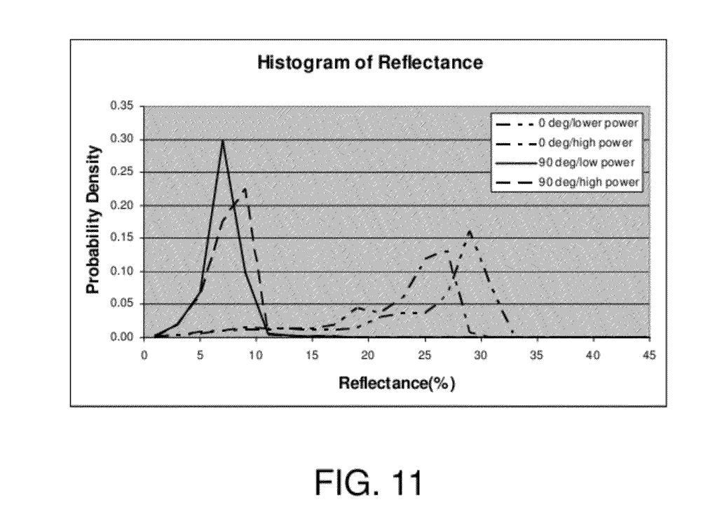

The experimental setup was used to measure the reflectivity of the surface from different orientations and incidence angles. In one orientation, a reflectivity difference was measured that exceeded 35%. In another orientation, the reflectivity difference measured was less than 10%. FIG. 11 shows a plot of the reflectivity versus probability density for the wafer was generated that indicated that the reflectivity difference for the wafer may be further reduced by increasing the incidence angle to 82°.

Thus, the experiment generally shows that it is possible to equalize the reflectivity between silicon areas and metal structures of patterned wafer to equalize the amount of heating in the various structures. Such equalization may involve directing a photonic beam with an appropriate polarization to an appropriately oriented wafer at an appropriate incidence angle. Typically, the illumination source has a wavelength much longer than the minimum structure dimension. For example, the wavelength-to-minimum-structure-dimension ratio may be greater than 100:1. In some instances, the incidence angle required to effect such equalization may be greater than the Brewster angle for the substrate to match the reflectivity between the two regions.

Thus, the invention also includes methods and apparatuses for selecting an optimal orientation and/or incidence angle for processing a surface of a substrate as described above with a photonic beam as described above. The methods and apparatuses involve directing the photonic beam toward the substrate surface at an incidence angle, scanning the photonic beam with respect to the substrate surface, and measuring radiation reflected from the substrate as a result. By rotating the substrate about the normal and/or changing the incidence angle while the beam illuminates the substrate, one may find the optimal orientation and/or incidence angles that correspond to a minimum in substrate surface reflectivity variations and/or maximum substrate surface reflectivity.

To ensure that the beam does not adversely affect the surface, the selection methods and apparatuses typically employ a beam power level less than that required to process the surface. Once the optimal orientation and/or incidence angle is found, the angle(s) may be programmed into an apparatus for processing the substrate surface. Such an apparatus may then be used at a beam power level required to process the surface of the substrate. The apparatus may also be used to process identical or similar substrate with identical or similar surface patterns and or reflectivities.

### Variations on the Invention

It will be apparent to those of ordinary skill in the art that the invention may be embodied in various forms. For example, high-power CO₂ lasers, e.g., having a power of at least 250 W, 1000 W, or 3500 W or higher, may be used to generate an image, which, in turn, is scanned across a surface of a substrate to effect rapid thermal processing, e.g., melt or non-melt processing, of the substrate surface. Such power levels may provide exposure energy doses of about 30 J/cm² or more over a 1 ms dwell time. Longer dwells require higher energies. The wavelength of the CO₂ laser, λ, is 10.6 μm in the infrared region, which is large relative to the typical dimensions of wafer features, and may therefore be uniformly absorbed as the beam scans across a patterned silicon wafer with the result that each point on the wafer is raised to very nearly the same maximum temperature.

Additional variations of the present invention will be apparent to those of ordinary skill in the art. For example, upon routine experimentation, those skilled in the art may find that the invention may be incorporated into existing equipment. Auxiliary subsystems known in the art may be used to stabilize the position and the width of the laser beam relative to the relay. Those of ordinary skill in the art will recognize that care must be taken to address to certain operational issues relating to the practice of the invention using powerful lasers to realize the full benefit of the invention.

It is to be understood that, while the invention has been described in conjunction with the preferred specific embodiments thereof, the foregoing description is intended to illustrate and not limit the scope of the invention. Any aspects of the invention discussed herein may be included or excluded as appropriate. For example, beam combining technologies and beam shaping technologies may be used by themselves or in combination. Other aspects, advantages, and modifications within the scope of the invention will be apparent to those skilled in the art to which the invention pertains.

All patents and patent applications mentioned herein are hereby incorporated by reference in their entireties to an extent not inconsistent with the above disclosure.

1-4. (canceled)

5. A method for processing a surface of a substrate having a surface normal and a surface pattern, comprising:
a. producing a photonic beam;
b. directing the photonic beam toward the substrate surface at an incidence angle with respect the surface normal and at an orientation angle of the beam relative to the surface pattern; and
c. scanning the beam across the substrate while maintaining the orientation angle and incidence angle at values selected to minimize substantially substrate surface reflectivity variations and/or minimize the substrate surface reflectivity during scanning.

6. The method of claim 5, wherein substrate surface exhibits a Brewster's angle and the selected incidence angle value is within about ±10° of the Brewster's angle.

7. The method of claim 5, wherein the beam is scanned in a manner so that substantially the entire substrate surface is heated to a uniform peak temperature.

8. The method of claim 5, wherein the photonic beam has a polarization plane, the surface pattern is formed from structures having lengths, and the substrate is oriented such that the polarization plane is substantially perpendicular to lengths of the structures.

9. The method of claim 7, wherein the peak temperature is greater than about 900° C.

10. The method of claim 7, wherein the beam is scanned in a manner such that substantially the entire substrate surface is heated to the uniform peak temperature for a period of time that does not exceed about 1 ms.

11-16. (canceled)

17. A method for processing a surface of a substrate, wherein the surface has a surface normal and a surface pattern that exhibits directionally and/or orientationally different reflectivities relative to radiation of a selected wavelength and polarization, comprising:
a. producing a photonic beam of the selected wavelength and polarization;
b. directing the beam toward the substrate; and
c. providing relative scanning movement between the stage and the beam while maintaining the substrate at a orientation angle value relative to the beam and the beam at incidence angle value relative to the substrate surface normal during scanning to minimize substantially substrate surface reflectivity variations and/or minimize the substrate surface reflectivity during scanning.

18. The method of claim 17, wherein step c. is carried out so that the substrate surface reflectivity variations does not exceed about 10%.

19. The method of claim 17, wherein step c. is carried out so that the maximum substrate surface reflectivity does not exceed about 20%.

20. A method for selecting an optimal orientation angle and/or incidence angle for processing a surface of a substrate with a photonic beam of a selected wavelength and polarization, wherein the surface has a surface normal and a surface pattern that exhibits directionally and/or orientationally different reflectivities relative to radiation of the selected wavelength and polarization, comprising:
a. directing the photonic beam toward the substrate surface at an incidence angle;
b. scanning the photonic beam with respect to the substrate surface;
c. measuring radiation reflected from the substrate during step b.; and
d. repeating steps a. through c. while rotating the substrate about the normal and/or changing the incidence angle to find the optimal orientation and/or incidence angles that correspond to a minimum in substrate surface reflectivity variations and/or minimize the substrate surface reflectivity.

21. The method of claim 20, wherein step d. is carried out employing a beam power level less than that required to process the surface.

22. The method of claim 20, further comprising, after step d.:
e. programming the optimal orientation angle into an apparatus for processing the substrate surface.

23. The method of claim 20, further comprising, after step d.:,
e. programming the optimal incidence angle into an apparatus for processing the substrate surface.

24. The method of claim 22, further comprising after step e.:
f. operating the apparatus at a beam power level required to process the surface.

25. The method of claim 24, further comprising after step e.:
f. operating the apparatus at a beam power level required to process a surface of another substrate.
